(19) United States
(12) Patent Application Publication
(10) Pub. No.: US 2009/0134387 A1
(43) Pub. Date: May 28, 2009

(54) CMOS SEMICONDUCTOR DEVICE

(75) Inventor: Gaku HARADA, Kawanishi-city (JP)

Correspondence Address: MOTS LAW, PLLC, 1629 K STREET N.W., SUITE 602, WASHINGTON, DC, 20006-1635, US

(73) Assignee: SANYO ELECTRIC CO., LTD., Moriguchi-city (JP)

(21) Appl. No.: 12/274,592

(22) Filed: Nov. 20, 2008

(30) Foreign Application Priority Data
Nov. 26, 2007 (JP) JP2007-304154

(51) Int. Cl. H01L 27/088; H01L 51/10

(52) U.S. Cl. 257/40; 257/369; 257/E51.006; 257/E27.06

(57) ABSTRACT

A CMOS semiconductor device includes a CMOS circuit that incorporates a P-channel field effect transistor connected to a first power source terminal and an N-channel field effect transistor connected to a second power source terminal that is lower in potential than the first power source terminal. The P-channel field effect transistor consists of a gate electrode, insulating film, drain electrode, first source electrode and first semiconductor layer. The N-channel field effect transistor consists of the gate electrode, insulating film, drain electrode, second source electrode and second semiconductor layer. The gate electrode serves as an input terminal of the CMOS circuit and the drain electrode serves as an output terminal of the CMOS circuit.

### BACKGROUND OF THE INVENTION

1. Technical Field

This invention relates to a CMOS semiconductor device which includes a CMOS circuit incorporating both P-channel and N-channel field effect transistors.

2. Description of Related Art

In recent years, an expanding attention has been focused upon organic thin-film devices using an organic material as an active material, in stead of conventional inorganic materials. Representing examples of organic thin-film devices include organic thin-film transistors and organic light-emitting devices. Since the organic thin-film devices are capable of film formation at a lower temperature, compared to silicon-based or other inorganic semiconductor devices, and can be deposited even on an ultra-light-weight, thin and flexible plastic substrate, they are highly expected to produce new devices and lower costs.

Representing examples of organic thin-film transistors using an organic semiconductor include a field effect transistor using polythiophene which is a high-molecular material (A. Tsumura, H. Koezuka and T. Ando, Appl. Phys. Lett., Vol. 49, p. 1210, 1986), and a field effect transistor using pentacene which is a low-molecular material (D. J. Gundlach, Y. Y. Lin, T. N. Jackson, S. F. Nelson and D. G. Schlom, IEEE Electron Device Lett., Vol. 18, p. 87, 1997). Both of them utilize a MOS-FET (Metal Oxide Semiconductor Field Effect Transistor) structure in which channel regions are provided parallel to a substrate. However, a high operating voltage, approximately 20-30 V, has prevented them from obtaining a sufficient drain current.

The drain current of the organic thin-film transistor can be increased, for example, by a method wherein a width of the channel region is expanded. However, the expanding width of the channel region expands an area that is occupied by the organic thin-film transistor. This results in lowering the aperture ratio, which is a problem. Also, the attempt to increase a panel luminance at a low aperture ratio results in a problem of a shortened life of the channel.

Alternatively, the drain current can be increased by a method wherein a length of the channel region is shortened. The reduction in length of the channel region can be accomplished, for example, by a method wherein the channel region is provided vertically and its length is limited by a thickness of the thin film (for example, Japanese Patent Laid-Open Nos. 2004-349292 and 2005-19446, and K. kudo, M. Tizuka, S. Kuniyoshi and K. Tanaka, Thin Solid Films, Vol. 393, p. 362, 2001).

As described above, in the vertical field effect transistors having the vertical channel region, a length of the channel region can be shortened with high precision and ease. Also, a source/drain electrode and a gate electrode can be formed in a self-alignment method.

By using such a vertical field effect transistor, a CMOS FET (complementary metal-oxide semiconductor field-effect transistor) circuit is realized which incorporates both P-channel and N-channel transistors. This CMOS circuit serves as a basic constituent element such as of a logical gate, memory IC, switching element or amplifying element.

Examples of CMOS structures using vertical transistors are disclosed, including a structure in which P-type and N-type transistors are arranged above each other and a gate electrode is formed through a gate oxide film (Japanese Patent Laid-Open No. Hei 6-45546) and a structure in which the respective drain electrodes of vertical P-type and N-type transistors are joined to each other (Japanese Patent Laid-Open No. 2003-179160).

Also, an example of a CMOS structure fabricated using an organic semiconductor is disclosed which incorporates both inorganic N-channel and organic P-channel transistors (Japanese Patent Laid-Open No. Hei 9-199732). Also, an example of a vertical inverter structure using an organic semiconductor is disclosed in which a source electrode, a semiconductor electrode and a drain electrode are superimposed in successive layers and a gate insulation film and an electrode layer are sequentially provided upright so as to contact one lateral side of a sequence of the three superimposed layers (Japanese Patent Laid-Open No. 2003-324198).

Also, an example of a vertical type CMOS structure fabricated using an inorganic semiconductor is disclosed in which N-channel and P-channel using the same semiconductor material are formed by ion doping (Japanese Patent Laid-Open No. 2004-327599).

However, these vertical CMOS circuits have a problem of complex structure, while capable of area reduction. Another problem is that fabrication as in a printing process, which is characteristic of devices using an organic semiconductor, is difficult to achieve.

### SUMMARY OF THE INVENTION

It is an object of the present invention to provide a CMOS semiconductor device which has a simple structure and allows size reduction.

The CMOS semiconductor device of the present invention includes a CMOS circuit which incorporates both a P-channel field effect transistor connected to a first power source terminal and an N-channel field effect transistor connected to a second power source terminal lower in potential than the first power source terminal. Characteristically, the CMOS semiconductor device has an insulating substrate, a gate electrode provided on the substrate and configured to project therefrom, an insulating film covering an upper surface and first and second lateral surfaces of the gate electrode, a drain electrode provided on the upper surface of the gate electrode through the insulating film, a first source electrode provided on the substrate on the first lateral surface side of the gate electrode and connected to the first power source terminal, a first semiconductor layer covering a space between the drain electrode and the first source electrode for defining a P-channel region, a second source electrode provided on the substrate on the second lateral surface side of the gate electrode and connected to the second power source terminal, and a second semiconductor layer covering a space between the drain electrode and the second source electrode for defining an N-channel region. The P-channel field effect transistor comprises the gate electrode, insulating film, drain electrode, first source electrode and first semiconductor layer. The N-channel field effect transistor comprises the gate electrode, insulating film, drain electrode, second source electrode and second semiconductor layer. The gate electrode serves as an input terminal of the CMOS circuit and the drain electrode serves as an output terminal of the CMOS circuit.

In the present invention, the first semiconductor layer is formed on the first lateral surface side of the projecting gate electrode to define the P-channel region, and the second semiconductor layer is formed on the second lateral surface side to define the N-channel region. The use of a single gate electrode in the formation of P-channel and N-channel field effect transistors and the common use of a drain electrode permit reduction of an overall size of the device. Also, the present invention uses an area for a single transistor in the formation of a CMOS circuit, as contrary to a conventional CMOS circuit which needs an area for two transistors; P-channel and N-channel field effect transistors. Accordingly, this also permits size reduction.

Also, the first and second semiconductor layers can be readily formed using an organic semiconductor material since they can be deposited as by a printing process.

In the present invention, the first and second semiconductor layers preferably comprise an organic semiconductor material. The use of the organic semiconductor material allows the first and second semiconductor layers to be deposited readily as by a printing or coating process.

Also in the present invention, the first and second semiconductor layers can be formed to have different channel widths. Accordingly, in the case where the first semiconductor layer material and the second semiconductor layer material exhibit different charge mobility characteristics, the current values through the P-channel and N-channel regions can be brought to nearly the same level by properly adjusting the channel widths thereof.

Also in the present invention, the gate electrode is preferably configured to define the first and second lateral surfaces that oppose to each other. In this case, the respective levels of current values of the P-channel and N-channel regions can be controlled by forming the first and second semiconductor layers to different channel widths, as described above. Also, in the case where either one of the first and second lateral surfaces of the gate electrode has a third lateral surface portion that extends toward the opposed lateral surface, one of the P-channel and N-channel field effect transistors may be formed to extend to this third lateral surface portion. This further expands a width of the channel region and permits adjustment of the width of channel region over a wider range.

In the present invention, the first semiconductor layer may comprise a p-type semiconductor layer and the second semiconductor layer may comprise an n-type semiconductor layer.

However, those first and second semiconductor layers may comprise a semiconductor layer having both p-type and n-type semiconductor characteristics. Even if the first and second semiconductor layers comprise such a semiconductor layer having both semiconductor characteristics, the first and second semiconductor layers can be utilized as the P-channel and N-channel regions, respectively, such as by a difference between voltages applied to these semiconductor layers.

The semiconductor layer having both semiconductor characteristics may be formed by using a mixture of a p-type semiconductor material and an n-type semiconductor material, or alternatively, by stacking a p-type semiconductor layer and an n-type semiconductor layer one above the other.

The use of such semiconductor layer having both semiconductor characteristics for the first and second semiconductor layers enables simultaneous formation thereof and accordingly simplifies a fabrication process.

The CMOS semiconductor device of the present invention includes a CMOS circuit. The most basic circuit may be a CMOS inverter circuit.

Alternatively, the CMOS semiconductor device of the present invention may incorporate a NAND circuit including a CMOS circuit.

In a preferred CMOS semiconductor device embodiment of the present invention which incorporates a NAND circuit, the device is characterized as further having second P-channel and second N-channel field effect transistors for formation of the NAND circuit. A source electrode of the second P-channel field effect transistor is connected to a first power source terminal. A drain electrode of the second P-channel field effect transistor and an output terminal of the CMOS circuit are connected to an output terminal of the NAND circuit. A source electrode of the second N-channel field effect transistor is connected to a second power source terminal. A drain electrode of the second N-channel field effect transistor is connected to a second source electrode of the CMOS circuit. An input terminal of the CMOS circuit is connected to a first input terminal. The respective gate electrodes of the second P-channel and second N-channel field effect transistors are connected to a second input terminal of the NAND circuit.

Alternatively, the CMOS semiconductor device of the present invention may incorporate a NOR circuit including a CMOS circuit.

In the preferred CMOS semiconductor device embodiment of the present invention which incorporates a NOR circuit, the device is characterized as further having a second P-channel field effect transistor and a second N-channel field effect transistor for formation of the NOR circuit. A source electrode of the second N-channel field effect transistor is connected to a second electrode terminal. A drain electrode of the second N-channel field effect transistor and an output terminal of the CMOS circuit are connected to an output terminal of the NOR circuit. A source electrode of the second P-channel field effect transistor is connected to a first electrode terminal. A drain electrode of the second N-channel field effect transistor is connected to a first source electrode of the CMOS circuit. A gate electrode of the second N-channel field effect transistor and a gate electrode of the second P-channel field effect transistor are connected to a first input terminal of the NOR circuit. An input terminal of the CMOS circuit is connected to a second input terminal of the NOR circuit.

The second P-channel and second N-channel field effect transistors are preferably in the form of a vertical field effect transistor, as similar to the field effect transistors which constitute the CMOS circuit. In such a case, each of the second P-channel and second N-channel field effect transistors may have, for example, a second gate electrode provided on the substrate and configured to project therefrom, a second insulating film covering an upper surface and lateral surfaces of the second gate electrode, an upper electrode provided on the upper surface of the second gate electrode through the second insulating film, a lower electrode provided on the substrate such that a region along the second insulating film on the lateral surface of the gate electrode defines a channel region between the upper electrode and the lower electrode, and a third semiconductor layer provided to cover a space between the upper electrode and the lower electrode for defining a channel.

The provision of the second P-channel and second N-channel field effect transistors each in the form of a vertical transistor, as described above, further simplifies a fabrication process and permits further size reduction.

The second gate electrode of the second P-channel field effect transistor may be integrally formed with the second gate electrode of the second N-channel field effect transistor. Such integral formation of these gate electrodes further simplifies a fabrication process and permits further side reduction.

For the second P-channel and second N-channel field effect transistors, channel regions may be formed in the respective third semiconductor layers provided on opposite lateral surfaces of the second gate electrode by disposing the lower electrodes on opposite sides of the second gate electrode so that one of the lower electrodes functions as a source electrode, the other lower electrode as a drain electrode and the upper electrode as a floating electrode. That is, the opposite lateral surfaces of the second gate electrode may be utilized to form the channel regions of the third semiconductor layers.

Alternatively, the channel region maybe formed in the third semiconductor layer provided solely on one lateral surface of the second gate electrode by disposing the lower electrode on the one lateral surface so that the lower electrode functions as a source electrode and the upper electrode as a drain electrode. That is, the third semiconductor layer may be provided solely on one lateral surface of the second gate electrode so that the channel region is formed solely on the one lateral surface.

In such cases, the second gate electrode may have a pair of lateral surfaces that oppose to each other. The third semiconductor layer of the second P-channel field effect transistor may be provided on one lateral surface of the second gate electrode and that of the second N-channel field effect transistor on the other lateral surface of the second gate electrode. Such provision of the P-channel and N-channel regions on different lateral surfaces of the second gate electrode expands a distance between the P-channel and N-channel regions, as well as preventing solutions containing organic semiconductors from mixing together when the P-channel and N-channel regions are formed as by an ink jet process.

The semiconductor layer in the present invention can be formed of an organic semiconductor material, as described above. Useful organic semiconductor materials include those having an electron-accepting function (n-type semiconductor materials) and those having an electron-donating function (p-type semiconductor materials). Examples of these materials are listed below.

Examples of useful electron-accepting materials include high-molecular organic compounds such as oligomers and polymers having pyridine or its derivatives in the skeleton, oligomers and polymers having quinoline or its derivatives in the skeleton, ladder polymers formed of benzophenanthrolines and their derivatives, and cyano-polyphenylenevinylenes; and low-molecular organic compounds such as fluorinated metal-free phthalocyanine, fluorinated metal phthalocyanines and their derivatives, perylene and its derivatives (e.g., PTCDA and PTCDI), napththalene derivatives (e.g., NTCDA and NTCDI), and bathocuproine and its derivatives.

Examples of useful electron-donating materials include high-molecular organic compounds such as oligomers and polymers having thiophene or its derivatives in the skeleton, oligomers and polymers having phenylenevinylene or its derivatives in the skeleton, oligomers and polymers having fluorene or its derivatives in the skeleton, oligomers and polymers having benzofuran or its derivatives in the skeleton, oligomers and polymers having thienylene-vinylene or its derivatives in the skeleton, oligomers and polymers having triphenylamine or other aromatic tertiary amines or their derivatives in the skeleton, oligomers and polymers having carbazole or its derivatives in the skeleton, oligomers and polymers having vinylcarbazole or its derivatives in the skeleton, oligomers and polymers having pyrrole or its derivatives in the skeleton, oligomers and polymers having acetylene or its derivatives in the skeleton, oligomers and polymers having isothianaphene or its derivatives in the skeleton, and oligomers and polymers having heptadiene or its derivatives in the skeleton; and low-molecular organic compounds such as metal-free phthalocyanines and metal phthalocyanines and their derivatives, diamines and phenyl diamines and their derivatives, acenes and their derivatives such as rubrene and pentacene, metal-free porphyrins and metal porphyrins and their derivatives such as porphyrin, tetramethylporphyrin, tetraphenylporphyrin, tetrabenzporphyrin, monoazotetrabenzporphyrin, diazotetrabenzporphyrin, triazotetrabenzporphyrin, octaethylporphyrin, octaalkylthioporphyrazine, octaalkylaminoporphyrazine, hemiporphyrazineandchlorophyll, and quinone dyes such as cyanine dyes, merocyanine dyes, squalirium dyes, quinacridone dyes, azo dyes, anthraquinone, benzoquinone and naphthoquinone.

Examples of useful central metals of metal phthalocyanines and metal porphyrins include metals such as magnesium, zinc, copper, silver, aluminum, silicon, titanium, vanadium, chromium, manganese, iron, cobalt, nickel, tin, platinum and lead; metal oxides; and metal halides.

For the semiconductor layers, the above-listed materials may be used alone. They may be dispersedly mixed in a proper binder material. Alternatively, the above-listed low-molecular organic compounds may be incorporated in a main or side chain of a proper high-molecular organic compound to provide materials for use in the semiconductor layers. Where the above-listed organic materials are dispersed in a binder material, fine particles of inorganic materials, e.g., fine particles of high-dielectric constant materials such as titanium oxide, zirconium oxide and barium titanate, maybe further added.

Examples of binder materials or high-molecular organic compounds constituting the main chain include polycarbonate resins, polyvinyl acetal resins, polyvinyl phenol resins, polyester resins, modified ether-type polyester resins, polyallylate resins, phenoxy resins, polyvinyl chloride resins, polyvinyl acetate resins, polyvinylidene chloride resins, polystyrene resins, acryl resins, methacryl resins, cellulose resins, urea resins, polyurethane resins, silicone resins, epoxy resins, polyamide resins, polyacrylamide resins and polyvinyl alcohol resins; copolymers and crosslinked products thereof; and photoconductive polymers such as polyvinyl carbazole and polysilane.

The method of forming the semiconductor layer is chosen depending upon the type of the semiconductor material used, but is generally chosen from a physical vapor deposition method (PVD method) illustrated by vacuum vapor deposition and sputtering, various chemical vapor deposition methods (CVD methods) and a spin coat method; a printing method such as screen printing or ink-jet printing; various coating methods including air doctor coater, blade coater, rod coater, knife coater, squeeze coater, reverse roll coater, transfer roll coater, gravure coater, kiss coater, cast coater, spray coater, slit orifice coater and calender coater methods and a dipping method; and a spraying method.

The insulating substrate in the present invention can be illustrated by various glass substrates with or without an insulating surface layer, a quartz substrate with or without an insulating surface layer, and a silicon substrate with an insulating surface layer. Another useful substrate example is a plastic substrate, either in the form of a film or sheet, which is composed of a polymeric material such as polyether sulfone (PES), polyimide, polycerbonate, polyethylene terephthalate (PET) or polyethylene naphthalate (PEN). The use of such a substrate comprised of a flexible polymeric material enables incorporation or integration of a field effect transistor into a display or electronic device such as having a curved surface.

Examples of materials useful for formation of the electrode in the present invention include metals such as gold (AU), platinum (Pt), aluminum (Al), copper (Cu), palladium (Pd), nickel (Ni), chromium (Cr), titanium (Ti), tantalum (Ta), tungsten (W) and niobium (Nb); alloys containing these metal elements; conductive particles composed of these metals; and conductive particles of alloys containing these metals.

If transparency is desired for the electrode, metal oxides such as indium tin oxide (ITO), fluorine-doped tin oxide, zinc oxide and tin oxide may be used. The above-listed variety of conductive polymeric materials can also be used.

In selecting the electrode material, its electrical properties (e.g., ohmic and schottky properties) with respect to the semiconductor layer is also taken into consideration. Although depending on the material used to constitute the gate electrode, formation of the gate electrode can be achieved by various methods, including a combination of a PVD method, e.g., a vacuum vapor deposition or sputtering method, and an etching technique; a combination of any of various CVD methods and an etching technique; a combination of a spin coat method and an etching technique; a printing method such as a screen or ink-jet printing method using a conductive paste or a solution of any of the above-listed various conductive polymeric materials, a liftoff method; a shadow mask method; a combination of any of the above-listed various coating methods and an etching technique; and a combination of a spraying method and an etching technique.

The insulating film in the present invention may be formed by oxidizing or nitriding a surface of the gate electrode, or alternatively, by depositing an oxide or nitride film on a surface of the gate electrode. Although depending on the material used to constitute the gate electrode, oxidation of the surface of gate electrode can be achieved by various methods, including an oxidizing method using an O₂ plasma and an anodizing method using a valve metal. Examples of the valve metal include Ta, Nb, Al and Ti.

Also, a nitriding method using an N₂ plasma can be employed to nitride the surface of gate electrode, although depending on the material used to constitute the gate electrode. The above-described methods are effective when the substrate is composed of a heat-resisting material.

In the case where low-temperature fabrication is carried out or a plastic substrate composed of a polymeric material is used, organic insulating materials capable of low-temperature treatment may be utilized, examples of which include organic materials such as a parylene resin, polycarbonate resin, polyvinyl acetal resin, polyester resin, modified ether-type polyester resin, polyallylate resin, phenoxy resin, polyvinyl chloride resin, polyvinyl acetate resin, polyvinylidene chloride resin, polystyrene resin, acryl resin, methacryl resin, cellulose resin, urea resin, polyurethane resin, silicone resin, epoxy resin, polyamide resin, polyacrylamide resin, polyvinyl phenol resin and polyvinyl alcohol resin, and copolymers and crosslinked products thereof.

A method useful for formation of the insulating film can be selected from various film-forming methods, examples of which include PVD methods illustrated by vacuum vapor deposition and sputtering methods; various CVD methods; spin coat methods; printing methods such as screen and ink-jet printing methods; the above-listed various coating methods; dipping methods; casting methods; and spraying methods. Also, in the case of an Au electrode, for example, insulating molecules capable of chemically forming bonds with the gate electrode, such as straight-chain hydrocarbon having an end modified with a mercapto group, may be applied onto a surface of the gate electrode as by a dipping method. Then, they cover the surface of gate electrode in a self-organizing manner to form the insulating film thereon.

In accordance with the present invention, a simple structure can be realized which permits formation of the semiconductor layer as by a printing or coating process and enables size reduction.

### BRIEF DESCRIPTION OF THE DRAWINGS

FIG. 1 is a sectional view which shows a first CMOS semiconductor device embodiment in accordance with the present invention;

FIG. 2 is a plan view which shows the first CMOS semiconductor device embodiment in accordance with the present invention;

FIG. 3 is a view which shows a CMOS inverter circuit in the embodiment shown in FIG. 1;

FIG. 4 is a schematic view which shows conditions in which semiconductor layers are formed by a vacuum vapor deposition method;

FIG. 5 is a sectional view which shows a second CMOS semiconductor device embodiment in accordance with the present invention;

FIG. 6 is a plan view which shows a third CMOS semiconductor device embodiment in accordance with the present invention;

FIG. 7 is a plan view which shows a fourth CMOS semiconductor device embodiment in accordance with the present invention;

FIG. 8 is a sectional view taken along the line C-C′ of FIG. 7;

FIG. 9 is a sectional view taken along the line B-B′ of FIG. 7;

FIG. 10 is a view which shows a NAND circuit of a fifth embodiment in accordance with the present invention;

FIG. 11 is a plan view which shows the fifth CMOS semiconductor device embodiment in accordance with the present invention;

FIG. 12 is a sectional view taken along the line A-A′ of FIG. 11;

FIG. 13 is a sectional view taken along the line B-B′ of FIG. 11;

FIG. 14 is a plan view which shows a sixth CMOS semiconductor device embodiment in accordance with the present invention;

FIG. 15 is a sectional view taken along the line A-A′ of FIG. 14;

FIG. 16 is a sectional view taken along the line B-B′ of FIG. 14;

FIG. 17 is a view which shows a NOR circuit of a seventh embodiment in accordance with the present invention;

FIG. 18 is a plan view which shows the seventh CMOS semiconductor device embodiment in accordance with the present invention;

FIG. 19 is a sectional view taken along the line A-A′ of FIG. 18; and

FIG. 20 is a sectional view taken along the line B-B′ of FIG. 18.

### DESCRIPTION OF THE PREFERRED EMBODIMENTS

The following specific embodiments illustrate the present invention but are not intended to be limiting thereof.

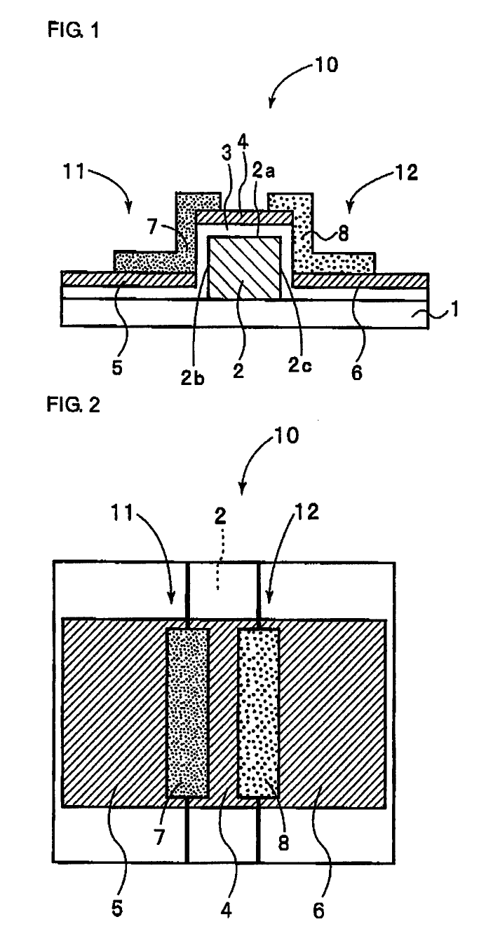

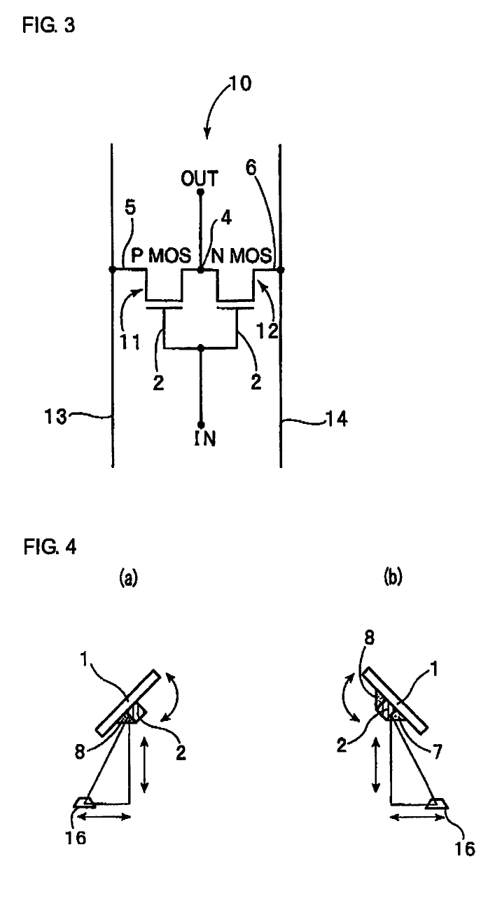

FIG. 1 is a sectional view which shows an embodiment of a CMOS semiconductor device in accordance with the present invention. In the CMOS semiconductor device of this embodiment, the CMOS inverter circuit shown in FIG. 3 is formed.

Referring to FIG. 3, a P-channel field effect transistor (P MOS) 11 and an N-channel field effect transistor (N MOS) 12 are disposed between a first power line 13 and a second power line 14. The second power line 14 has a lower potential than the first power line 13. In this embodiment, it is grounded.

A source electrode 5 of the P-channel field effect transistor 11 is connected to the first power line 13. A source electrode 6 of the N-channel field effect transistor 12 is connected to the second power line 14. The P-channel field effect transistor 11 and N-channel field effect transistor 12 have a common drain electrode which is connected to an output terminal OUT.

A gate electrode 2 of the P-channel field effect transistor 11 and a gate electrode 2 of the N-channel field effect transistor 12 are respectively connected to an input terminal IN.

The CMOS circuit shown in FIG. 3 is a CMOS inverter circuit 10 where an input signal from the input terminal IN is inverted and then sent from the output terminal OUT.

FIG. 1 is a sectional view which shows an element structure of the CMOS inverter circuit 10 shown in FIG. 3. Disposed on an insulating substrate 1 is a gate electrode 2 which is configured to project from the substrate 1. The substrate 1 comprises a glass substrate and the gate electrode 2 is composed of aluminum. The gate electrode 2 is 1 μm high and 10 μm wide. The gate electrode 2 can be patterned by depositing aluminum on the substrate 1 by a vapor deposition or sputtering technique, applying a resist film to provide a mask and then performing wet etching.

An insulating film 3 is deposited to cover an upper surface 2a and lateral surfaces 2b and 2c of the gate electrode 2 and the substrate 1. In this embodiment, the insulating film 3 comprises Parylene C and is deposited to a thickness of 250 nm.

A drain electrode 4 is formed on the upper surface 2a of the gate electrode 2 through the insulating film 3. A first source electrode 5 is formed, through the insulating film 3, on the substrate 1 on the first lateral surface 2b side of the gate electrode 2. A second source electrode 6 is formed, through the insulating film 3, on the substrate 1 on the second lateral surface 2c side of the gate electrode 2. The drain electrode 4, first source electrode 5 and second source electrode 6 are formed by vapor depositing gold over an entire surface of the insulating film 3 to a thickness of 100 nm and then etch removing the deposited gold film from regions of the insulating film 3 that correspond respectively to the first lateral surface 2b and the second lateral surface 2c. Etching can be achieved by using an etchant (product of Kanto Chemical Co., Inc., product name “AURUM 302”). Gold can be deposited over an entire surface of the insulating film 3, for example, by a method wherein vapor deposition is effected while rotating the substrate 1 at a slope.

Subsequently, a first semiconductor layer 7 is deposited to cover a region of the insulating film 3 that overlies the first lateral surface 2b of the gate electrode 2. Deposition of the first semiconductor layer 7 is carried out by applying a solution of poly(3-hexylthiophene), which is a p-type semiconductor material, by an ink jet printer.

Similarly, a second semiconductor layer 8 is deposited to cover a region of the insulating film 3 that overlies the second lateral surface 2c of the gate electrode 2. Deposition of the second semiconductor layer 7 is carried out applying a solution of PCBM (6,6-phenyl-C61-butyric acid methyl ester), an n-type semiconductor material, by an ink jet printer.

The organic semiconductor solution is formed into a film in the following fashion. As the ink jet printer causes the organic semiconductor solution to drop over a portion of the insulating film 3 that covers the first or second lateral surface 2b or 2c of the gate electrode, as described above, droplets of the solution gather at a corner defined by the insulating film 3 on the lateral surface and the first or second source electrode 5 or 6, rise due to surface tension and then cover the insulating film 3 on the lateral surface in a self-alignment method.

The first semiconductor layer 7, a p-type semiconductor layer, is deposited such that it covers a space between the drain electrode 4 and the first source electrode 5. Deposition of the semiconductor layer 7 results in the formation of a P-channel field effect transistor 11 which includes the gate electrode 2, insulating film 3, drain electrode 4, first source electrode 5 and first semiconductor layer 7.

Similarly, the second semiconductor layer 8, an n-type semiconductor layer, is deposited such that it covers a space between the drain electrode 4 and the second source electrode 6. This results in the formation of an N-channel field effect transistor 12 which includes the gate electrode 2, insulating film 3, drain electrode 4, second source electrode 6 and second semiconductor layer 8.

As shown in FIG. 3, the first source electrode 5 is connected to a first power line 13 and the second source electrode 6 is connected to a second power line 14.

FIG. 2 is a plan view of the first embodiment shown in FIG. 1. As shown in FIG. 2, the first semiconductor layer 7 extends between the first source electrode 5 and the drain electrode 4, while the second semiconductor layer 8 extends between the drain electrode 4 and the second source electrode 6.

In the fashion as described above, the P-channel field effect transistor 11 is formed on the first lateral surface 2b side of the gate electrode 2 and the N-channel field effect transistor 12 is formed on the second lateral surface 2c side of the gate electrode 2. The P-channel field effect transistor 11 and N-channel field effect transistor 12 share the gate electrode 2 and the drain electrode 4. Accordingly, the P-channel field effect transistor 11 and N-channel field effect transistor 12 are connected to each other not only at the gate electrode 2 but also at the drain electrode 4, and constitute a CMOS inverter circuit which includes the gate electrode 2 as an input terminal IN and the drain electrode 4 as an output terminal OUT.

In the preceding embodiment, the first semiconductor layer 7 and second semiconductor layer 8 are deposited in a printing process by an ink jet printer. However, the present invention is not limited thereto. They may be vapor deposited under vacuum, for example.

FIG. 4 is a schematic view which explains a procedure by which such semiconductor layers are deposited by a vacuum vapor deposition method.

As shown in FIG. 4(a), the substrate 1 is inclined such that one lateral surface of the gate electrode 2 opposes to a vapor deposition source 16. In this condition, the second semiconductor layer 8, for example, is formed by a vacuum vapor deposition method.

Next, the substrate 1 is inclined such that another lateral surface of the gate electrode 2 opposes to the vapor deposition source 16, as shown in FIG. 4(b). In this condition, the first semiconductor layer 7 is formed by a vacuum vapor deposition method.

The formation of semiconductor layers by using a vacuum vapor deposition method, as described above, eliminates the need of a mask for film formation pattern.

Also in the first embodiment, the first semiconductor layer and second semiconductor layers are described to comprise a p-type semiconductor layer and an n-type semiconductor layer, respectively. However, in the present invention, the first and second semiconductor layers may comprise a semiconductor layer having both p-type and n-type semiconductor characteristics.

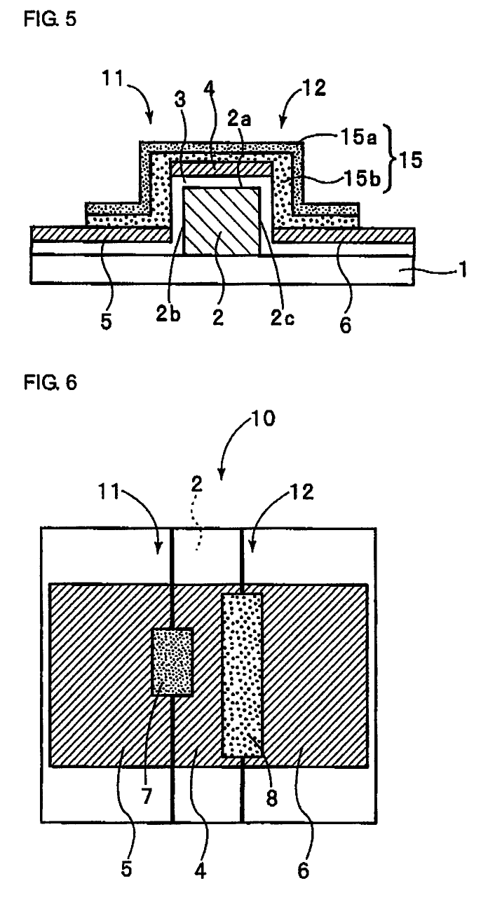

FIG. 5 is a sectional view which shows a second CMOS semiconductor device embodiment as its first and second semiconductor layers comprise a semiconductor layer having both semiconductor characteristics.

As shown in FIG. 5, in this embodiment, an n-type semiconductor layer 15b and an overlying p-type semiconductor layer 15a constitute a semiconductor layer 15 having both semiconductor characteristics that serves as the first or second semiconductor layer.

In such a case where the semiconductor layer 15 has both semiconductor characteristics, if a voltage is applied to each electrode, the semiconductor layer 15 of the P-channel field effect transistor 11 functions as a P-channel region and the semiconductor layer 15 of the N-channel field effect transistor 12 functions as an N-channel region.

The utilization of the semiconductor layer 15 having both semiconductor characteristics, as described above, enables use of the common semiconductor layer in the P-channel and N-channel field effect transistors 11 and 12. This eliminates the need of depositing semiconductor layers in their respective patterns and allows them to be deposited, for example, by a spin coating method.

FIG. 6 is a plan view which shows a third embodiment of the CMOS semiconductor device in accordance with the present invention. In this embodiment, the first semiconductor layer 7 is shortened in length to narrow a P-channel region and the second semiconductor layer 8 is expanded in length to widen an N-channel region. Excepting this feature, the preceding first embodiment is followed to fabricate a CMOS semiconductor device.

The first and second semiconductor layers 7 and 8 comprise a p-type semiconductor material and an n-type semiconductor material, respectively. In the case where the p-type and n-type semiconductor materials have different properties, e.g., have different mobilities, the current values of the P-channel and N-channel field effect transistors can be brought to a nearly equal level by properly changing the channel widths thereof. The mobility of PCBM for use as the n-type semiconductor material is 0.02 cm²/V·cm and that of poly(3-hexylthiophene) for use as the p-type semiconductor material is 0.03 cm²/V·cm. In this particular case, the current values of the P-channel and N-channel field effect transistors can be brought to a nearly equal level by expanding the channel width of the N-channel field effect transistor to 1.5 times of that of the P-channel field effect transistor.

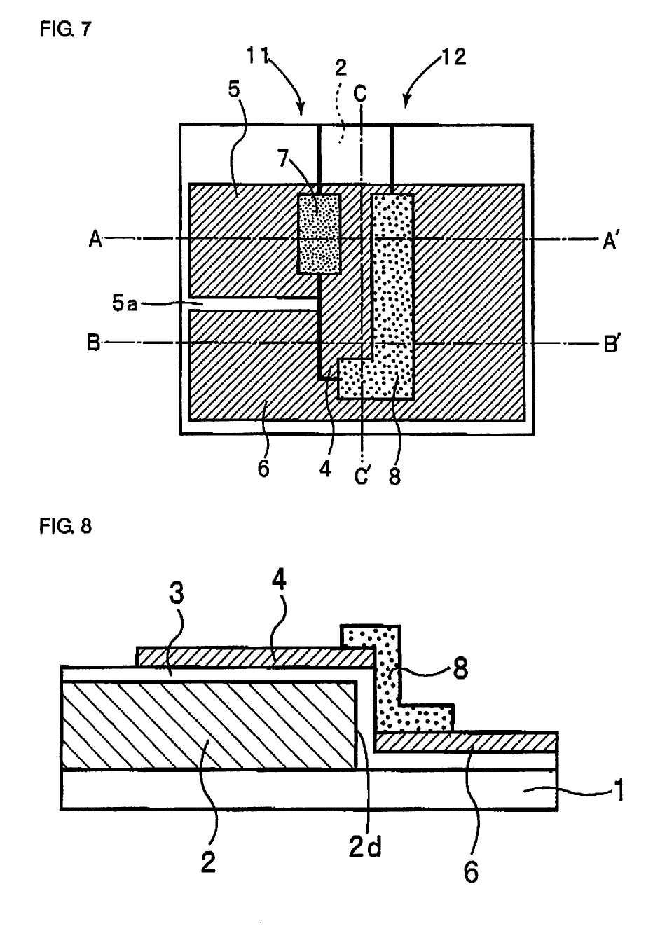

FIG. 7 is a plan view which shows a fourth embodiment of the CMOS semiconductor device in accordance with the present invention.

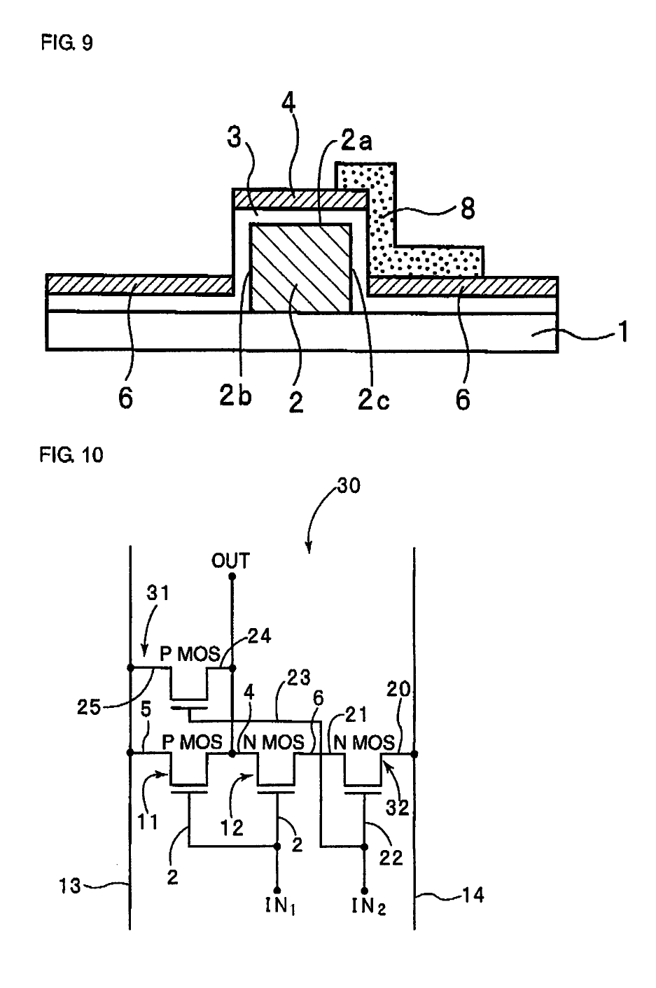

FIG. 8 is a sectional view taken along the line C-C′ of FIG. 7. FIG. 9 is a sectional view taken along the line B-B′ of FIG. 7. As shown in FIG. 8, the gate electrode 2 extends to a middle position of the semiconductor device to define a third lateral surface 2d. The sectional view taken along the line A-A′ of FIG. 7 corresponds to the sectional view shown in FIG. 1.

As shown in FIG. 7, in this embodiment, an end of the second semiconductor layer 8 further extends along the third lateral surface 2d of the gate electrode 2, so that the channel width of the second semiconductor layer 8 is further extended.

In this embodiment, the insulating film 3 is deposited on the gate electrode 2 and the substrate 1. Subsequently, gold is deposited over an entire surface thereof. Thereafter, those portions of the deposited film on the insulating film 3 that correspond to the lateral surfaces 2b, 2c and 2d of the gate electrode 2 are removed by etching. Also, a portion of the deposited film in a separation region 5a is removed to separate the first and second source electrodes 5 and 6 from each other, as shown in FIG. 7. The second source electrode 6 further extends round toward the F-channel field effect transistor 11, as shown in FIG. 7.

The procedure of this embodiment can be utilized when desired to further expand a channel width of either one of semiconductor layers.

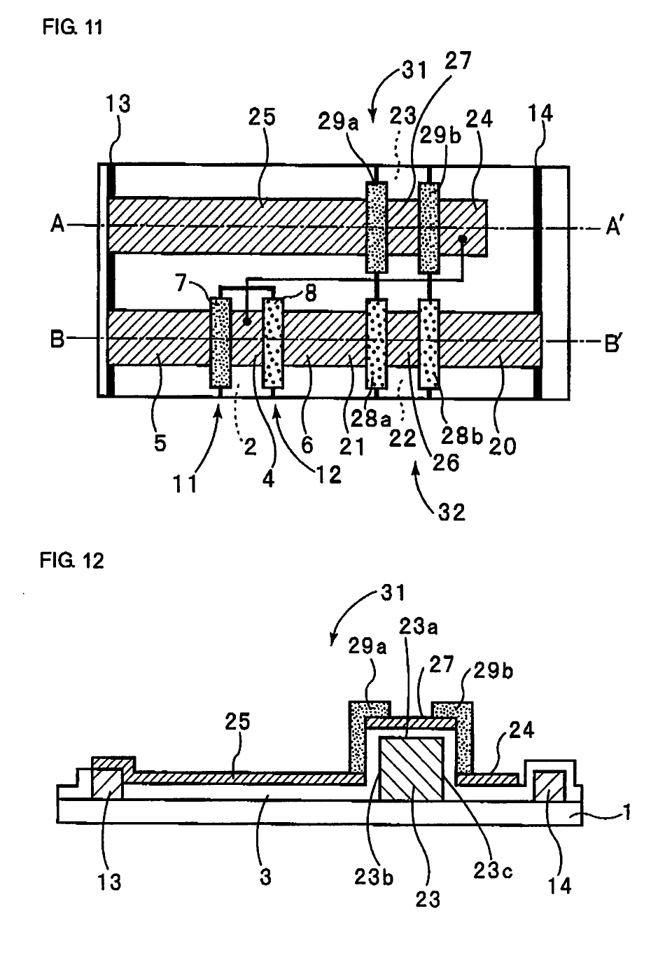

FIG. 11 is a plan view which shows a fifth embodiment of the CMOS semiconductor device in accordance with the present invention.

In the embodiment shown in FIG. 11, the CMOS semiconductor device incorporates the NAND circuit 30 shown in FIG. 10. Similar to the embodiment shown in FIG. 3, the NAND circuit shown in FIG. 10 includes the first P-channel field effect transistor 11 and the first N-channel field effect transistor 12 which together constitute a CMOS circuit. In this embodiment, the device further includes a second P-channel field effect transistor 31 and an N-channel field effect transistor 32.

A source electrode 25 of the second P-channel field effect transistor 31 is connected to the first power line 13. A drain electrode 24 of the second P-channel field effect transistor 31 is connected to the drain electrode 4 serving as an output terminal of the CMOS circuit and also to an output terminal OUT of the NAND circuit. A source electrode 20 of the second N-channel field effect transistor 32 is connected to the second power line 14. A drain electrode 21 of the second N-channel field effect transistor 32 is connected to the second source electrode 6 of the CMOS circuit.

The gate electrode 2 serving as the input terminal of the CMOS circuit is connected to a first input terminal IN₁ of the NAND circuit. A gate electrode 23 of the second P-channel field effect transistor 31 is connected to a gate electrode 22 of the second N-channel field effect transistor. These electrodes are connected to a second input terminal IN₂ of the NAND circuit.

The NAND circuit 30 of this embodiment is constituted as outlined above.

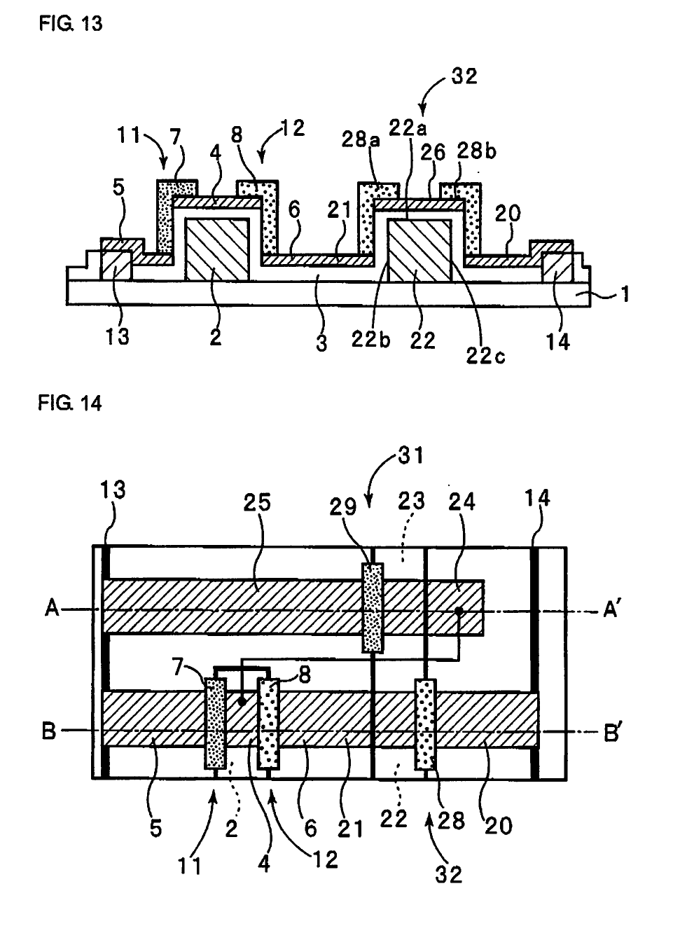

FIG. 11 is a plan view which shows a semiconductor device incorporating the NAND circuit shown in FIG. 10. FIG. 12 is a sectional view taken along the line A-A′ of FIG. 11. FIG. 13 is a sectional view taken along the line B-B′ of FIG. 11.

As shown in FIG. 13, the first P-channel and first N-channel field effect transistors 11 and 12 are constructed in the same manner as in the above first embodiment. The first source electrode 5 is connected to the first power line 13. The second source electrode 6 is connected to the drain electrode 21 of the neighboring second N-channel field effect transistor 32.

The second N-channel field effect transistor 32 is fabricated in the following fashion.

The second gate electrode 22 is formed on the substrate 1. The insulating film 3 is deposited to cover upper and lateral surfaces of the second gate electrode 22. A floating electrode 26 is deposited on the upper surface 22a of the gate electrode 22 through the insulating film 3. The drain electrode 21 is formed on the first lateral surface 22b side of the gate electrode 22. The drain electrode 21 is integrally formed with the second source electrode 6 for connection therebetween. On the second lateral surface 22c side of the gate electrode 22, the source electrode 20 is formed on the substrate 1 through the insulating film 3. This source electrode 20 is connected to the second power line 14. The drain electrode 21, source electrode 20 and floating electrode 26 may comprise the same metal film as the drain electrode 4, first source electrode 5 and second source electrode 6, i.e., may comprise a deposited gold film. Similar to the first embodiment, the metal film deposited on regions of the insulating film 3 that correspond to the first lateral surface 22b and second lateral surface 22c of the gate electrode 22 may be etch removed so that the source electrode 20, drain electrode 21 and floating electrode 26 can be patterned.

Similar to the first and second semiconductor layers 7 and 8, third semiconductor layers 28a and 28b, each composed of an n-type semiconductor material, are deposited as by an ink jet process to cover regions of the insulating film 3 that overlie the first lateral surface 22b and second lateral surface 22c.

In the fashion as outlined above, the N-channel field effect transistor 32 can be formed which comprises the second gate electrode 22, insulating film 3, source electrode 20, drain electrode 21, floating electrode 26 and third semiconductor layers 28a and 28b.

In the second N-channel field effect transistor 32, a sum of a distance between the source electrode 20 and the floating electrode 26 and a distance between the floating electrode 26 and the drain electrode 21 is a channel length.

The second P-channel field effect transistor 31 has a construction shown in FIG. 12. The second gate electrode 23 is formed on the substrate 1. The floating electrode 27 is formed on an upper surface 23a of the second gate electrode 23 through the insulating film 3. On the first lateral surface 23b side of the second gate electrode 23, the source electrode 25 is formed on the substrate 1 through the insulating film 3. The source electrode 25 is connected to the first power line 13.

On the second lateral surface 23c side of the second gate electrode 23, the drain electrode 24 is formed on the substrate 1 through the insulating film 3. The drain electrode 24, source electrode 25 and floating electrode 27 can be formed in the same manner as the source electrode 20, drain electrode 21 and floating electrode 26 of the second N-channel field effect transistor 32 shown in FIG. 13.

Third semiconductor layers 29a and 29b, each comprised of a p-type semiconductor material, are deposited to cover regions of the insulating layer 3 that overlie the first lateral surface 23b and second lateral surface 23c of the gate electrode 23.

The second P-channel field effect transistor 31 comprises the gate electrode 23, insulating film 3, source electrode 25, drain electrode 24, floating electrode 27 and third semiconductor layers 29a and 29b. A channel length of the second P-channel field effect transistor 31 is a sum of a distance between the drain electrode 24 and the floating electrode 27 and a distance between the floating electrode 27 and the source electrode 25.

The drain electrode 24 of the thus-formed second P-channel field effect transistor 31 is connected to the drain electrode 4 of the first P-channel field effect transistor and the first N-channel field effect transistor, as shown in FIG. 11, thereby forming the NAND circuit 30 shown in FIG. 10.

As shown in FIG. 11, the gate electrode 23 of the second P-channel field effect transistor 31 is integrally formed with the gate electrode 22 of the second N-channel field effect transistor 32. This establishes electrical connection between the second gate electrode 22 and the second gate electrode 23 and also simplifies a fabrication process.

In this embodiment, the gate electrode 2 serves as the first input terminal IN₁, the second gate electrode 22 as the second input terminal IN₂ and the drain electrode 24 of the second P-channel field effect transistor 31 as the output terminal OUT.

FIG. 14 is a plan view which shows a sixth embodiment of the CMOS semiconductor device in accordance with the present invention. In this embodiment, the NAND circuit shown in FIG. 10 is formed in the same manner as in the fifth embodiment.

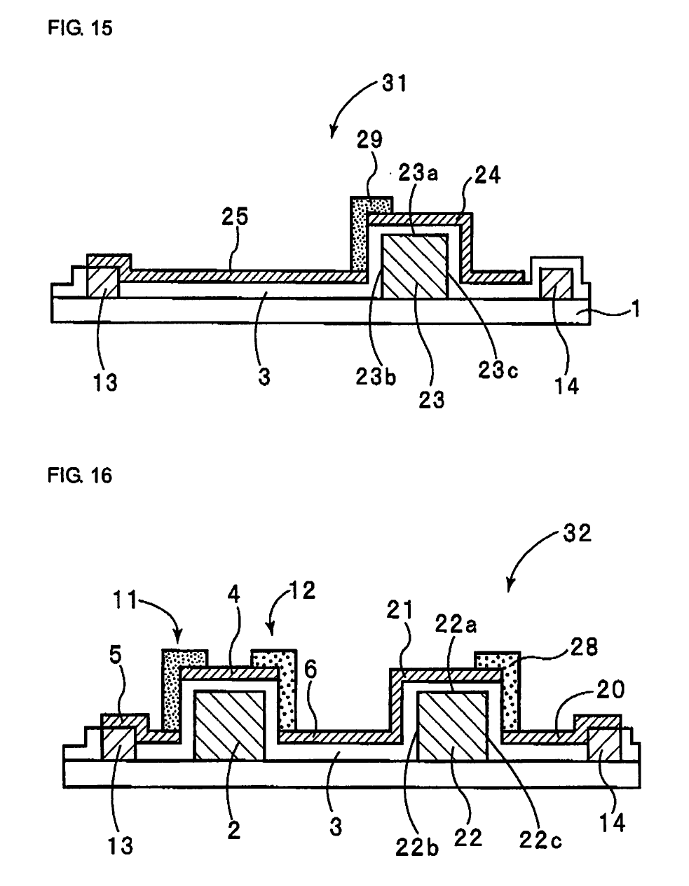

FIG. 15 is a sectional view taken along the line A-A′ of FIG. 14. As shown in FIGS. 14 and 15, in this embodiment, a third semiconductor layer 29 is formed solely on the first lateral surface 23b side of the second gate electrode 23. Accordingly, only a metal film portion on the insulating film 3 that overlies the first lateral surface 23b is etched, while a metal film portion on the insulating film 3 that overlies the second lateral surface 23c remains unetched, so that the drain electrode 24 is formed in a manner to extend upwardly onto the upper surface 23a of the second gate electrode 23.

In the second P-channel field effect transistor 31 of this embodiment, the third semiconductor layer 29 is only formed on one lateral surface. Accordingly, a distance from a leading edge of the drain electrode 24 to the source electrode 25 is a channel length.

FIG. 16 is a sectional view taken along the line B-B′ of FIG. 14.

As shown in FIG. 16, in the second N-channel field effect transistor 32 of this embodiment, a third semiconductor layer 28 is formed solely on the second lateral surface 22c side of the gate electrode 22. Accordingly, only a metal film portion on the insulating film 3 that overlies the second lateral surface 22c is removed, while a metal film portion on the insulating film 3 that overlies the first lateral surface 22b remains unremoved, so that the drain electrode 21 is formed to extend upwardly onto the upper surface 22a of the second gate electrode 22.

In the second N-channel field effect transistor 32, a distance from a leading edge of the drain electrode 21 to the source electrode 20 is a channel length.

Also in this embodiment, the second gate electrode 22 of the second N-channel field effect transistor 32 is integrally formed with the second gate electrode 23 of the second P-channel field effect transistor 31, as shown in FIG. 14, thereby providing electrical connection between the second gate electrode 22 and the second gate electrode 23.

As also shown in FIG. 14, the drain electrode 24 is electrically connected to the drain electrode 4.

Also in the NAND circuit of this embodiment, the gate electrode 2 serves as the first input terminal IN₁, the second gate electrode 22 as the second input terminal IN₂ and the drain electrode 24 as the output terminal OUT.

As shown in FIG. 14, in this embodiment, the third semiconductor layer 29 of the second P-channel field effect transistor 31 is formed on one lateral surface of the gate electrode 23, while the third semiconductor layer 28 of the second N-channel field effect transistor 32 is formed on the opposite lateral surface. This expands a spacing between the third semiconductor layer 29 and the third semiconductor layer 28 and shortens the possibility of semiconductor layer forming materials mixing together in the formation of these semiconductor layers.

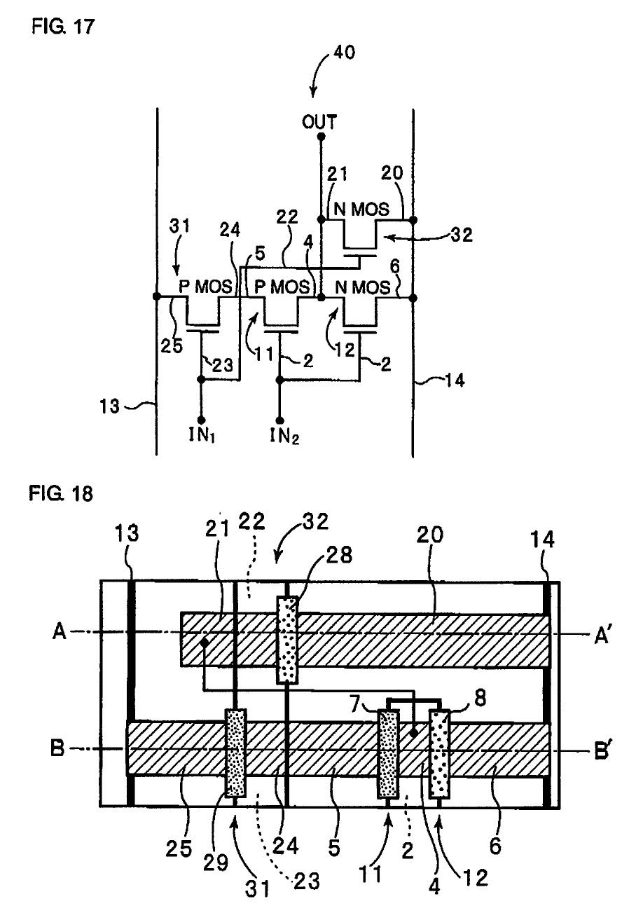

FIG. 18 is a plan view which shows a seventh embodiment of the CMOS semiconductor device in accordance with the present invention. In this embodiment, the NOR circuit 40 shown in FIG. 17 is formed.

As shown in FIG. 17, the second source electrode 6 of the first N-channel field effect transistor 12 is connected to the second power line 14. The first source electrode 5 of the first P-channel field effect transistor 11 is connected to the drain electrode 24 of the neighboring second P-channel field effect transistor 31. The source electrode 25 of the second P-channel field effect transistor 31 is connected to the first power line 13.

The source electrode 20 of the second N-channel field effect transistor 32 is connected to the second power line 14. The drain electrode 21 of the second N-channel field effect transistor 32 is connected to the drain electrode 4 and to the output terminal OUT. The gate electrode 22 of the second N-channel field effect transistor 32 is connected to the gate electrode 23 of the second P-channel field effect transistor 31 and to the first input terminal IN₁.

The gate electrode 2 serving as the input terminal of the CMOS circuit is connected to the second input terminal IN₂.

FIG. 20 is a sectional view taken along the line B-B′ of FIG. 18. As shown in FIG. 20, the first P-channel field effect transistor 11 and first N-channel field effect transistor 12 are constructed in the same manner as in the first embodiment. The second source electrode 6 is connected to the second power line 14.

Also, the second P-channel field effect transistor 31 is formed in the same manner as in the embodiment shown in FIG. 15. Its source electrode 25 is connected to the first power line 13 and its drain electrode 24 is connected to the first source electrode 5.

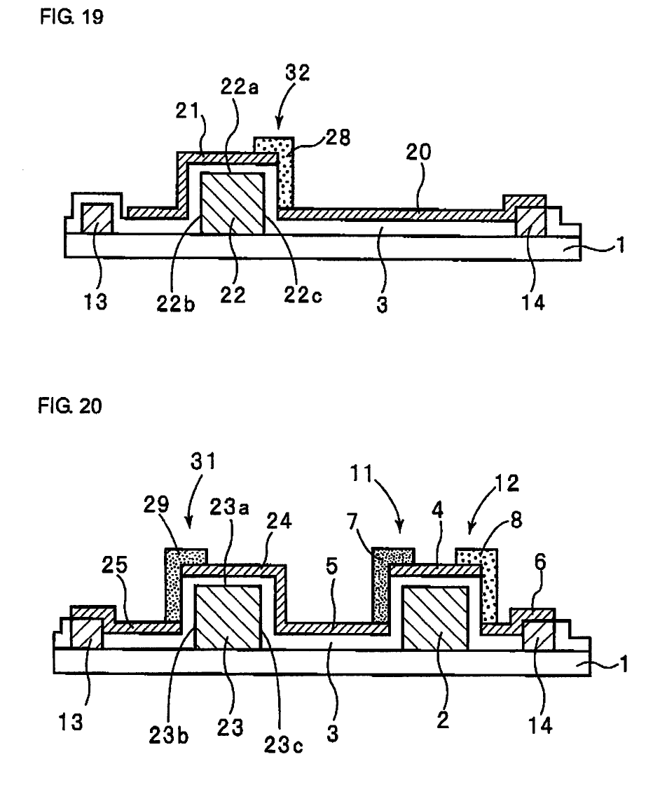

FIG. 19 is a sectional view taken along the line A-A′ of FIG. 18. As shown in FIG. 19, the second N-channel field effect transistor 32 is constructed in the same manner as in the embodiment shown in FIG. 16 and its source electrode 20 is connected to the second power line 14.

As also shown in FIG. 18, the drain electrode 21 of the second N-channel field effect transistor 32 is connected to the drain electrode 4 of the CMOS circuit.

Also in this embodiment, the second gate electrode 23 of the second P-channel field effect transistor 31 is integrally formed with the second gate electrode 22 of the second N-channel field effect transistor 32, as shown in FIG. 18, thereby providing electrical connection between the second gate electrode 23 and the second gate electrode 22.

Also in this embodiment, the third semiconductor layer 29 of the second P-channel field effect transistor 31 and the third semiconductor layer 28 of the second N-channel field effect transistor 32 are formed on lateral surfaces opposite to each other. This arrangement prevents semiconductor materials from mixing together in the formation of these semiconductor layers.

As described above, a CMOS inverter circuit, NAND and NOR circuits each incorporating the CMOS inverter circuit can be formed in a simple structure. Also, the opposite lateral surfaces of a gate electrode of a vertical field effect transistor are utilized to form two field effect transistors, thereby enabling size reduction.

What is claimed is:

1. A CMOS semiconductor device which includes a CMOS circuit incorporating a P-channel field effect transistor connected to a first power source terminal and an N-channel field effect transistor connected to a second power source terminal lower in potential than the first power source terminal, said CMOS semiconductor device comprising:
an insulating substrate;
a gate electrode provided on said substrate and configured to project from said substrate;
an insulating film covering an upper surface, a first lateral surface and a second lateral surface of said gate electrode;
a drain electrode provided on said upper surface of the gate electrode through the insulating film;
a first source electrode provided on said substrate on the first lateral surface side of the gate electrode and connected to said first power source terminal;
a first semiconductor layer covering a space between the drain electrode and the first source electrode for defining a P-channel region;
a second source electrode provided on said substrate on the second lateral surface side of the gate electrode and connected to said second power source terminal; and
a second semiconductor layer covering a space between the drain electrode and the second source electrode for defining an N-channel region;
wherein said P-channel field effect transistor is composed of said gate electrode, said insulating film, said drain electrode, said first source electrode and said first semiconductor layer; said N-channel field effect transistor is composed of said gate electrode, said insulating film, said drain electrode, said second source electrode and said second semiconductor layer; said gate electrode serves as an input terminal of the CMOS circuit; and said drain electrode serves as an output terminal of the CMOS circuit.

2. The CMOS semiconductor device as recited in claim 1, wherein said first and second semiconductor layers comprise an organic semiconductor material.

3. The CMOS semiconductor device as recited in claim 1, wherein the respective channel regions of said first and second semiconductor layers have different widths.

4. The CMOS semiconductor device as recited in claim 1, wherein said first and second lateral surfaces of the gate electrode oppose to each other.

5. The CMOS semiconductor device as recited in claim 4, wherein either one of said first and second lateral surfaces has a third lateral surface portion that extends toward the other lateral surface, and that one of said P-channel and N-channel field effect transistors extends to said third lateral surface portion.

6. The CMOS semiconductor device as recited in claim 1, wherein said first semiconductor layer comprises a p-type semiconductor layer and said second semiconductor layer comprises an n-type semiconductor layer.

7. The CMOS semiconductor device as recited in claim 1, wherein said first and second semiconductor layers comprise a semiconductor layer having both p-type and n-type semiconductor characteristics.

8. The CMOS semiconductor device as recited in claim 7, wherein said semiconductor layer having both semiconductor characteristics comprises a laminate of the p-type semiconductor layer and the n-type semiconductor layer.

9. The CMOS semiconductor device as recited in claim 1, wherein said CMOS circuit is a CMOS inverter circuit.

10. The CMOS semiconductor device as recited in claim 1, wherein it incorporates a NAND circuit including said CMOS circuit.

11. The CMOS semiconductor device as recited in claim 10, wherein it further includes a second P-channel field effect transistor and a second N-channel field effect transistor for said NAND circuit,
wherein a source electrode of said second P-channel field effect transistor is connected to said first power source terminal, and a drain electrode of said second P-channel field effect transistor and said output terminal of the CMOS circuit are connected to an output terminal of the NAND circuit,
wherein a source electrode of said second N-channel field effect transistor is connected to said second power source terminal, and a drain electrode of the second N-channel field effect transistor is connected to said second source electrode of the CMOS circuit, and
wherein said input terminal of the CMOS circuit is connected to a first input terminal of the NAND circuit, and the respective gate electrodes of the second P-channel field effect transistor and the second N-channel field effect transistor are connected to a second input terminal of the NAND circuit.

12. The CMOS semiconductor device as recited in claim 1, wherein it incorporates a NOR circuit including said CMOS circuit.

13. The CMOS semiconductor device as recited in claim 12, wherein it further includes a second P-channel field effect transistor and a second N-channel field effect transistor for said NOR circuit,
wherein a source electrode of said second N-channel field effect transistor is connected to said second power source terminal, and a drain electrode of said second N-channel field effect transistor and the output terminal of the CMOS circuit are connected to an output terminal of the NOR circuit,
wherein a source electrode of said second P-channel field effect transistor is connected to the first power source terminal, and a drain electrode of the second N-channel field effect transistor is connected to said first source electrode of the CMOS circuit, and
wherein the respective gate electrodes of the second N-channel field effect transistor and the second P-channel field effect transistor are connected to a first input terminal of the NOR circuit, and said input terminal of the CMOS circuit is connected to a second input terminal of the NOR circuit.

14. The CMOS semiconductor device as recited in claim 11, wherein each of said second N-channel field effect transistor and said second P-channel field effect transistor includes:
a second gate electrode provided on said substrate and configured to project from said substrate;
a second insulating film covering an upper surface and lateral surfaces of said second gate electrode;
an upper electrode provided on the upper surface of the second gate electrode through said second insulating film;
a lower electrode provided on the substrate so that a region along the second insulating film on the lateral surface of the gate electrode defines a channel region between said upper electrode and said lower electrode; and
a third semiconductor layer for covering the upper electrode and the lower electrode so that said channel is formed.

15. The CMOS semiconductor device as recited in claim 14, wherein said second gate electrode of the second P-channel field effect transistor is integrally formed with said second gate electrode of the second N-channel field effect transistor.

16. The CMOS semiconductor device as recited in claim 14, wherein the channel regions are defined in the respective third semiconductor layers provided on opposite lateral surfaces of said second gate electrode by disposing the lower electrodes on opposite sides of the second gate electrode, respectively, so that one of the lower electrodes functions as a source electrode, the other lower electrode as a drain electrode and the upper electrode as a floating electrode.

17. The CMOS semiconductor device as recited in claim 14, wherein the channel region is defined in the third semiconductor layer provided solely on one lateral surface of said second gate electrode by disposing the lower electrode on the one lateral surface so that the lower electrode functions as a source electrode and the upper electrode as a drain electrode.

18. The CMOS semiconductor device as recited in claim 17, wherein said second gate electrode has a pair of lateral surfaces that oppose to each other, the third semiconductor layer of the second P-channel field effect transistor is provided on one said lateral surface of the second gate electrode, and the third semiconductor layer of the second N-channel field effect transistor is provided on the other said lateral surface of the second gate electrode.
